(19) United States
(12) Patent Application Publication
(10) Pub. No.: US 2026/0050703 A1
(43) Pub. Date: Feb. 19, 2026

(54) METHODS FOR MANUFACTURING AND FINISHING MUSICAL INSTRUMENTS AND RELATED COMPONENTS

(71) Applicants: Garrett Bruce Becwar, Cave Creek, AZ (US); Justin Rollefson, Tempe, AZ (US)

(72) Inventors: Garrett Bruce Becwar, Cave Creek, AZ (US); Justin Rollefson, Tempe, AZ (US)

(73) Assignee: RolBec Instruments LLC, Cave Creek, AZ (US)

(21) Appl. No.: 18/802,298

(22) Filed: Aug. 13, 2024

(51) Int. Cl. G06F 30/17; B33Y 40/10; B33Y 40/20; B33Y 50/00; B33Y 80/00; G06T 17/00

(52) U.S. Cl. CPC G06F 30/17; B33Y 40/10; B33Y 40/20; B33Y 50/00; B33Y 80/00; G06T 17/00

(57) ABSTRACT

A method for manufacturing at least one of a musical instrument, musical instrument section, musical instrument part, and musical instrument accessories utilizes computer-assisted drawing software to prepare a digital model of the at least one of the musical instrument, the musical instrument section, the musical instrument part, or the musical instrument accessory to be manufactured. The digital model is sliced. One may then select a material for the at least one of the musical instrument, the musical instrument section, the musical instrument part, or the musical instrument accessory to be manufactured. One may prepare the selected material. One may them build the digital model layer by layer using the material, until at least one of a three-dimensional musical instrument, musical instrument section, musical instrument part, or musical instrument accessory is formed.

### TECHNICAL FIELD

The present application relates generally to musical instruments and related sections, parts, and accessories and, more specifically, to methods for manufacturing and finishing musical instruments and related sections, parts, and accessories that alter and improve musical instruments and their manufacturing.

### BACKGROUND

Musical instruments have been an essential part of human history, cultural importance and social gatherings. Some of the earliest known musical instruments include drums and other forms of percussion instruments, string instruments such as the harp and lyre, and wind instruments such as the aulos. Musical instruments are typically classified according to five general categories based on the manner in which the instruments produce their respective sounds, including strings (e.g. violin, viola, cello, double bass, harp, guitar), woodwinds (e.g. saxophone, silver Western flute, oboe, English horn, clarinet, bassoon, recorder, shakuhachi, duduk, dizi), brass winds (e.g. trumpet, French horn, trombone, baritone horn, tuba, flugelhorn, cornet, euphonium), percussion (e.g. timpani, snare drum, bass drum, cymbals, castanets, gong), and keyboards (e.g. organ, piano, harpsichord, celeste).

Regarding the production of sound, string instruments produce sound through the vibration of their strings from that act of being bowed, plucked, strummed, or struck. Woodwind instruments produce sound by an airstream, typically produced by the player, being split and causing an oscillation of the air within the resonating tube of the instrument producing the sound. Woodwinds use two main forms of sound sources to produce the oscillation: a vibrating reed or a splitting edge. Brass instruments produce sound by the vibration of a player's lips against a cup-shaped mouthpiece, causing the air column inside the instrument to oscillate. This vibration is amplified and shaped by the instrument's tubing and bell. Percussion instruments produce sound by being shaken, plucked, scraped, or the like, or struck by a player with sticks, mallets, or the like. Keyboard instruments produce sound, for example, by mechanical actuated striking or plucking of strings, upon a player depressing one or more keys. More recently, contemporary electronic musical instruments have been developed. These instruments receive sounds from a corresponding computer interface.

Over time, various methods have evolved for crafting and manufacturing musical instruments, from rudimentary ancient forms utilizing objects found in nature, such as animal horns, bones and skin, conch shells, clay, wood, and the like, to later-developed techniques that are still practiced today, such as woodworking, metalworking and metal beating methods, lutherie, and the like.

With respect to metal wind instruments, which includes metal instruments in the woodwind and brass families such as the piccolo, flute, saxophone, trumpet, French horn, trombone, and tuba, and the like, at present, metal wind instruments generally undergo an extensive and labor-intensive process to be manufactured. Typically, this process begins with forming the body tubes of the particular instrument. Thin sheets of brass or other suitable metal material are cut and hand-bent into shapes that form the tubes of the body sections using jigs and mandrels, to form consistent pieces. Next, these shapes are joined together at the seams using soldering or brazing to create a seamless air-tight body. Yamaha®, a well-known musical instrument manufacturer, uses another method for manufacturing metal wind instruments involving a hydroforming process which uses half molds of instrument bodies (e.g. saxophone bodies) and pressurized oil to form sheets of brass into half body parts. These are then soldered together to make whole bodies.

After either of these processes are performed, the formed body shape is typically refined through a hammering process involving annealing, heating and cooling the metal, to soften the metal for the shaping process. Mandrels are then used to create the bell flare and bends of the body, as well as socket connection points. If the body requires tone holes, these are typically formed next. Tone holes are typically crafted through two different methods: in one method, the holes are drilled or punched into the body and tone hole chimney, where the raised area of the tone hole is soldered into place around the tone hole. In another method the tone holes are extruded from the metal body which involves a metal die inside the body extruding a raised tone hole from the material as the die is pulled through. After the tone holes and hole chimneys are created, posts and supports for all the key work are measured and soldered into place on the body. Once all the key work, including the rods and key cups are produced, they are attached to the body of the horn. Next, the springs and any other parts needed for the particular instrument are installed. The final step in the manufacturing process is typically applying lacquer or plating as the finishing process.

There are a number of drawbacks associated with the aforementioned processes for manufacturing metal wind instruments. For example, the current metal wind instrument manufacturing process hinders variety, efficiency, and environmental responsibility. In this regard, the extensive labor involved in this manufacturing process often translates to months-long production times, especially for professional and custom instruments. Each intricate part undergoes manual crafting and soldering, demanding a workforce with specialized skills and bespoke machinery. This labor-intensive approach unfortunately introduces inconsistency, as human error leads to very loose tolerances and craftsmanship, rendering materials unusable.

Relatedly, error, mediocre manufacturing methods, or the like can lead to production of instruments with subpar sound and/or tonal characteristics, as well. Furthermore, material options remain largely confined to brass and silver and with limited adjustments available in composition, thickness, and coating. Design innovation is equally constrained by the casting and molding methods employed, restricting how manufacturers can experiment with new shapes and sounds. Finally, this process raises concerns about its environmental impact. The current metal wind instrument manufacturing process leaves a hefty environmental footprint through polluting chemicals, wasteful materials, outdated machinery, and limited recycling options, demanding a greener approach for the future. In light of these limitations, it is evident that metal wind instrument manufacturing is in need of a revolution, one that prioritizes speed, consistency, customization, and sustainable practices.

Recently, concerns for the environment and desires to develop sustainable practices have become increasingly popular, including in the field of manufacturing in general. This has led to the development of various sustainable manufacturing technologies that are vastly more environmental-friendly compared to their earlier counterparts. Some examples of such manufacturing technologies include additive manufacturing, electroplating, and electroless plating, each of which will be discussed in turn below.

Additive manufacturing (hereinafter “AM”), also known as three-dimensional (hereinafter “3D”) printing, generally refers to technologies capable of generating 3D objects from a digital blueprint (file or model) by adding a selected build material in a layer-by-layer fashion to create the particular object. The digital blueprint is typically generated through the use of computer-aided design (hereinafter “CAD”) software. Unlike traditional subtractive manufacturing processes that carve away material resulting in large amounts of waste, additive manufacturing processes build objects one layer at a time in the shape of the component with minimal wasted material. This process unlocks a world of freedom through the creation of unparalleled designs and material complexity. Two forms of additive manufacturing have been generally recognized in particular, depending on the materials utilized to fabricate the particular object. These forms include metal additive manufacturing and non-metal additive manufacturing.

The current main forms of 3d printing include: Vat photopolymerization, Material Jetting, Binder Jetting, Material extrusion, powder bed fusion, sheet lamination and Directed Energy Deposition.

Vat photopolymerization uses a vat filled with the desired build material, typically a liquid photopolymer material or resin, out of which the model is constructed layer by layer through a process of photopolymerization achieve by using a thermal source, typically a UV light to cure or harden the selected build material one layer at a time. The platform moves downwards after each layer is cured until the component is complete. Post processing might include: removing the component from the vat, removing excess selected build material, removing supports, and a final thermal source curing process.

Material jetting creates the component by jetting droplets of material onto a build platform using either a continuous or Drop on Demand (DOD) process. Droplets of material are deposited from the print head onto the build area, using either thermal or piezoelectric methods of controlling the deposition of material. The material layers are then cured or hardened using a thermal source, typically a UV light, building the component layer by layer. Post Processing can include: removing excess build material.

Binder jetting uses two materials, a selected build material and a binder, for building a component. The binder is usually in a liquid form and material is usually in a powder form. The print head moves across the build area depositing alternating layers of material and binder until the component is complete. Post processing can include: removing excess material, allowing time for the binding agent to solidify, or a heated curing process.

Material extrusion process involves drawing material through a thermal source heated nozzle and depositing the selected build material layer by layer to produce the component. Post processing can include: removing excess material and removing supports

The Powder Bed Fusion process involves the spreading of the selected build material, usually in a powder form, in a layer and using a thermal source to bond the powder together. These steps are repeated layer by layer to produce the final component. The Powder Bed Fusion process includes the following commonly used printing techniques: Direct metal laser sintering (DMLS), Electron beam melting (EBM), Selective heat sintering (SHS), Selective laser melting (SLM) and Selective laser sintering (SLS). Post processing can include: removing excess material, further cleaning, machining, sintering to improve homogenization of selected build material, and hot isostatic pressing to strengthen the component.

Sheet lamination builds a component by binding sheets or ribbons of the selected build material together to form the component. The material is bound to the previous layer. Then a thermal source is used to remove excess material from the desired shape of the layer. This process is repeated layer by layer until the final component is completed. This process includes ultrasonic additive manufacturing (UAM) and laminated object manufacturing (LOM). Post Processing can include: removing excess material and machining.

Directed Energy Deposition (DED) is the process of using a nozzle and a thermal source mounted on a multi axis arm, which deposits the selected build material that is melted upon deposition using a thermal and solidifies. Material is deposited layer by layer until the final component is completed. This process includes: Laser engineered net shaping, directed light fabrication, direct metal deposition, and 3D laser cladding.

A binder or binding agent is, typically, a liquid used between the layers of selected build material to bind the material together in certain additive manufacturing processes. The binder solidifies on contact or through a post process.

A thermal source is used in some forms of additive manufacturing. It is typically used as a way to melt or bind the selected build material into the form of the component. Some thermal sources include UV lights, lasers, electron beams, and heated nozzles.

Heat Treating is a process that may include heating and cooling of components to change their microstructure and mechanical properties. The process may improve the strength, hardness, and fatigue resistance while reducing internal stresses and dimensional variations of the component. Additionally, heat treating can improve the formation between selected build materials and corrosion resistance. A few example processes of heat treating may include sintering, hot isostatic pressing and fast quenching.

Post Processing can additionally include aesthetic steps such as: polish, buffing, lacquering and painting. Polishing involves rubbing the surface with an abrasive material to smoothen the surface to achieve the desired aesthetic. Polishing finishes can range from brushed, matte, and up to a mirror finish. Buffing is the process of rubbing a surface with a loose abrasive material. The process can also include a compound to aid in the buffing process. Buffing removes fine cosmetic defects from the surface. Lacquering is a process that involves applying a clear coating to the outside to protect it from scratches and other wear and tear, while maintaining its appearance. Lacquer is a type of reactive finish, which hardens through a chemical reaction that involves solvent evaporation and polymerization. The lacquering dries when the solvent evaporates or is accelerated by a curing process. Coating an instrument refers to the application of popular coating techniques including shellac, paint and oil finish.

Metal additive manufacturing (hereinafter “MAM”), also commonly known as metal 3D printing, is becoming an increasingly popular method of more sustainable manufacturing. Over time, MAM has transformed into a revolutionary manufacturing technique, crafting intricate objects from a digital model. Unlike traditional subtractive manufacturing methods, this additive process builds objects layer-by-layer. This process unlocks a world of design freedom through the creation of unparalleled designs and material complexity.

Some commonly known MAM processes include the following: selective laser melting (hereinafter “SLM”), direct metal laser sintering (hereinafter “DMLS”), electron beam melting (hereinafter “EBM”), and binder jetting. Some of the key industrial fields that currently embrace this transformative technology include aerospace parts, automotive parts, medical implants and devices, jewelry creation, an array of consumer goods, and energy components.

Various metals can be used in metal 3D printing. Such metals include, but are not limited to, the following:
Stainless steel: 316L, 17-4, 420, maraging steel
Aluminum: AlSi10Mg, Al6061, Scalmalloy®
Titanium: Ti6Al4V, grade 2, CP titanium
Nickel alloys: Inconel® 625, IN718, Hastelloy® X
Copper: C101, C102, C110
Silver: sterling silver, silver-palladium alloys, silver-copper alloys; other special alloys: silver-gold alloys and silver-infiltrated metal powders
Brass: free-machining brass (C360), leaded brass (C260/C280), lead-free brass (C355), high-zinc brass (C510/C521), naval brass (C464), silicon brass, aluminum brass

There are two main types of metal printing technologies/fabrication methods that are predominant in the industrial fields mentioned above. These two types are powder bed fusion (hereinafter “PBF”) and bound metal deposition (hereinafter “BMD”). PBF utilizes a high-power laser or electron beam to selectively melt metal powder layer-by-layer, fusing the powder into a solid form. Popular PBF techniques include SLM for fully melting the powder and DMLS for partially fusing it, creating a denser structure. BMD resembles traditional fused deposition modeling (hereinafter “FDM”) printers, using a nozzle to extrude a metal-polymer composite filament. The printed part then undergoes post-processing, typically involving heat treatment, to remove the polymer and sinter the metal particles together.

Understanding general printing parameters helps to achieve further understanding of these different metal printing methods. PBF and BMD techniques require parameters based on the particular metal powder or filament selected. The most common metal powders chosen for these techniques are alloys such as titanium or stainless steel. Material data sheets often provide recommended settings for various properties such as surface finish, mechanical strength, and build speed.

PBF's laser power determines the amount of energy delivered to the metal powder, influencing melt pool depth, layer thickness, and overall build speed. Higher power melts deeper, creating thicker layers but potentially inducing residual stress. The scan speed governs how quickly the laser beam traverses the powder bed, affecting melt pool size and heat distribution. Slower speeds ensure thorough melting but take longer, while faster speeds can lead to incomplete melting and surface roughness. Layer thickness defines the individual layer height added to the build. Thicker layers offer faster build times but might compromise surface finish and resolution. Conversely, thin layers offer finer details but lengthen the printing process. Hatch spacing dictates the distance between individual laser scan lines within a layer. Overlapping scan lines ensure complete melting but waste time and material. Wider spacing reduces build time but might cause gaps or inconsistencies. An inert gas is used, typically argon, to fill the build chamber to prevent oxidation of the molten metal and ensure consistent print quality. Proper gas flow influences temperature control and minimizes material contamination. Finally, the temperature for PBF typically occurs at elevated temperatures to preheat the build platform and prevent thermal shock during melting. This preheating can range from 150° C. to 250° C. depending on the material and printer specifics.

BMD's nozzle temperature is crucial for melting the metal-polymer composite filament and ensuring proper extrusion. Insufficient temperature leads to incomplete melting and potential clogging, while excessive heat can degrade the filament and compromise printability. The print speed influences overall build time but affects filament deposition and layer quality. Rapid printing might cause inconsistencies or gaps, while slower speeds offer better control but lengthen the process. Flow rate determines the amount of filament extruded per unit time, impacting layer thickness and material deposition consistency. Overfeeding can lead to excess material and potential warping, while underfeeding results in thin layers and potential gaps. Following printing, the composite parts undergo separate thermal processes. Debinding involves heating the part to remove the polymer binder, typically at temperatures around 400° C. to 500° C. Sintering then fuses the remaining metal particles together, typically at higher temperatures (900° C. to 1400° C.) depending on the metal used.

An alternative to MAM or metal 3D printing is non-metal 3D printing, also known as non-metal additive manufacturing. Non-metal additive manufacturing is somewhat similar to MAM, but employs materials other than metal in the fabrication process. In non-metal additive manufacturing, as in MAM, physical 3D objects are created by depositing material in a layer-by-layer process. Common materials used in non-metal additive manufacturing include, but are not limited to, the following: polymers, plastics, ceramics, composites, and the like. Generally, the materials utilized in non-metal additive manufacturing will depend on the particular object that is to be produced., including its desired qualities and characteristics. Some qualities often taken into consideration include the size and scale of the object, whether resistance to corrosion or moisture or other effects is desired, and the time and costs involved in producing the object.

In non-metal additive manufacturing, numerous different materials can be utilized, such as polymers/plastics (e.g. ABS, polycarbonate and nylon; other thermoplastics include polypropylene, polyethylene, PTFE, PEEK, PETG, PMMA, POM, PVC and PVDF; common polymer thermosets include epoxy, phenolic, melamine, silicone and polyester); composites (e.g. fiberglass-reinforced plastics (FRP), carbon fiber-reinforced plastics (CFRP) and any other fiber-reinforced polymers); ceramics (e.g. alumina, zirconia, silicon nitride, silicon carbide, porcelain and the crystalline structure form of glass (in which atoms are arranged in a regular, repeating pattern); glass (e.g. any amorphous structure of glass (in which atoms are arranged randomly without a defined lattice; and other materials (wood, paper, and textiles), for example.

Turning now to electroplating, also known as electrochemical deposition or electrodeposition, electroplating is a well-known process and commonly used in the fields of aerospace, automotive, medical, dental, decorative arts, and the like. Generally, in the electroplating process, a metal is layered or coated onto another metal by a process using an electric current to dissolve metal and coat it onto the surface to be plated. Electroplating is utilized in many different industries. With regard to metal musical instruments, electroplating is a versatile plating method process typically used by manufacturers. Electroplating is generally efficient, cost effective, precise, and allows for controlled plating thickness and uniformity. Benefits of electroplating a musical instrument include enhanced durability and corrosion resistance, improved sound quality, and aesthetic appeal.

Electroless plating is also a well-known process and commonly used in the fields of electronics, aerospace, automotive, and the like. In one form of electroless plating, a non-metal material is coated with an autocatalytic process through which metals or metal alloys are deposited, not electrically. Unlike electroplating, electroless plating does not require direct electrical contact, allowing for uniform coating on any surface, including irregularly shaped portions, holes, edges, and the like. Benefits of using electroless plating include improved wear resistance and lubricity and solderability, improved sound quality, and aesthetic appeal.

Various non-metal materials can be electroless plated. Examples of such materials include, but are not limited to, the following:
Polymers/plastics: Commonly known polymers/thermoplastics that can be electroless plated include: ABS, polycarbonate, and nylon. Other thermoplastics include: polypropylene, polyethylene, PTFE, PEEK, PETG, PMMA, POM, PVC, and PVDF. Commonly known polymer thermosets include: epoxy, phenolic, melamine, silicone, and polyester.
Composites: Commonly known composites that can be electroless plated include: fiberglass-reinforced plastics (hereinafter “FRP”), carbon fiber-reinforced plastics (hereinafter “CFRP”), and any other fiber-reinforced polymers.
Ceramics: Commonly known ceramics that can be electroless plated include:

alumina, zirconia, silicon nitride, silicon carbide, porcelain, and the crystalline structure form of glass (whereby atoms are arranged in a regular, repeating pattern).
Glass: Commonly known glass structures that can be electroless plated include any amorphous structure of glass (whereby atoms arranged randomly without a defined lattice).
Other materials: Other materials that can be electroless plated but that require special pre-treatment include: wood, paper, rubber, and textiles.

It should be noted that the foregoing list may not include every possible material currently compatible with electroless plating or that will become compatible in the future with electroless plating. Additionally, some materials may require specific modifications or pre-treatment processes to be suitable for electroless plating. Suitability of a material for electroless plating varies depending on the particular material's temperature stability, chemical resistance, surface properties, cost, and complexity.

Various metals can be used to plate non-metal materials during the electroless plating process. Such metals and metal alloys include, but are not limited to, the following:
Stainless steel: Stainless steel has excellent corrosion resistance, good strength, good weldability, and a wide range of available grades. Popular choices include 316L (high corrosion resistance), 17-4 PH (high strength and heat treatability), and Inconel® 625 (exceptional high-temperature strength and corrosion resistance).
Tool steels: Tool steels are used when circumstances require cutting-edge performance in tooling and die applications. Commonly used tool steels include: H13 (hot work), S7 (shock resistance), and M2 (high hardness).

Each of these also exhibits extreme wear resistance, high hardness and hot hardness, and good heat treatability.
Titanium: Lightweight and incredibly strong (due to its exceptional strength-to-weight ratio), titanium is commonly used in the aerospace and medical applications industries where weight reduction, corrosion resistance and biocompatibility are crucial. Common alloys include Ti6Al4V (general-purpose), Ti-6Al-7Nb (high strength), and CP Ti (high biocompatibility). In addition to these common titanium types, some beta titanium alloys are becoming increasingly popular which include: Ti-10V-2Fe-3Al and Ti-15Mo.
Aluminum: The automotive, aerospace, and consumer goods industries commonly use aluminum for its affordability, low weight, strength and good conductivity. Commonly known aluminum alloys include: AlSi10Mg (good casting), Al6061 (high strength), and A356 (high wear resistance). Other known aluminum alloys include: AlSi7Mg0.6, AlSi9Cu3, AA2121, and Scalmalloy®.
Nickel-based alloys: Nickel-based alloys are commonly revered for their exceptional high-temperature strength, corrosion resistance, and oxidation resistance. Commonly known nickel-based alloys include: Inconel® 718 (high-temperature strength), Hastelloy® C-276 (outstanding corrosion resistance), and Rene 88 DT (good fatigue resistance).
Chrome alloys: Several chrome alloys are commonly used and referred to as “workhorses” in electroless plating processes. Nickel-chromium is commonly regarded as the most-used chrome alloy for its hardness, corrosion resistance, good solderability and aesthetic appeal. Other nickel alloys that are also common and share most of the same characteristics as nickel-chromium include chromium-tungsten and chromium-boron. Less common options include chromium-molybdenum and chromium-silicon.
Copper alloys. Copper itself boasts fantastic electrical and thermal conductivity, making it a valuable material for various applications. However, pure copper's softness and susceptibility to oxidation limit its use in demanding scenarios. Copper alloys commonly used in electroless plating (as well as electroplating) include: C101 (ETP copper), C102 (oxygen-free high conductivity copper) and C106 (cupronic nickel-copper-nickel alloy). Many other copper alloys have been created for various applications. These other alloys include GRCop alloys (42, 84), C18150 (CuCr1Zr), C18200 (CuCr), GlidCop, other copper-nickel alloys (C70600 (CuNi10Fe1Mn), C71500 (CuNi 10Sn)), copper-chromium-zirconium alloys (CuCr0.5Zr, CuCr1Zr), copper-silver alloys (C70250 (CuAg25), C72400 (CuAg0.10P)) and specialty copper alloys (copper-beryllium, copper-phosphorus, copper-tin).
Refractory metals. Tungsten, molybdenum, niobium and tantalum offer unmatched melting points and high-temperature strength, pushing the boundaries in rocket engines, nuclear reactors, and aerospace components.

Common refractory metals include tungsten alloys (W—Ni, W—Re), molybdenum alloys (Mo—Ni, Mo—La), tantalum alloys (Ta—W, Ta—Hf), niobium alloys (Nb—Ti, Nb—Zr) and rhenium alloys (Re—W, Re—Os).
Other nickel and nickel alloys. Other nickel and nickel-alloys also offer great corrosion-resistance, wear-resistance, strength and thermal conductivity.

These nickel and nickel-alloy types include Inconel® (625, 939), Haynes® (282®, 214®, 556®), Rene 41, Nimonic® (75, 80A), nickel-copper alloys such as Monel® (400, K500) and nickel-chromium alloys (Nicrobraze®, Invar®).
Precious metal alloys. Precious metals not only add aesthetics but also add strength, malleability, ductility, corrosion resistance, and conductivity to an object. Precious metal alloys include gold alloys (18kt yellow, white, and rose gold, Au—Pt, Au—Ag), silver alloys (sterling silver, Ag—Pd, Ag—Cu), platinum alloys (Pt—Ir, Pt—Ru, Pt—Co), and palladium alloys (Au—Al, Pd—Cr, Pt—Rh).
Tin alloys. Tin alloys generally have desirable conductivity, corrosion resistance, and wear resistance capabilities. Further, tin alloys are also used for their good castability and solderability. Commonly known tin alloys include tin-bronze alloys (CuSn10P, CuSn6, CuSn5Zn5Pb2), tin-silver alloys (Sn60Ag40, Sn95Ag5), tin-bismuth alloys (Sn91Bi9, Sn85Bi15), tin-zinc alloys (Sn85Zn15, Sn63Zn37) and tin-indium alloys (Sn62In38, Sn50In50).
Other Steels and Steel Alloys. Other steel and steel alloy types that can also be used in electroless plating (as well as electroplating) include maraging steels (AISI 1815L, AISI 4340M), low-alloy steels (EN 1.7225 (4140), ASTM A500) and nickel-alloyed steels (4340, 9Ni).
Titanium alloys. Titanium is a relatively extremely light but strong material. Common types of titanium alloys include Ti-6Al-4V-ELI, Ti-38-6Nb and Ti-6Al-4V-Pd.
Cobalt-chromium alloys. Cobalt-chromium alloys are known for their exceptional strength, wear resistance, and biocompatibility. Some types of cobalt-chromium alloys include CoCrMo (ASTM F75), Elgiloy®, Stellite® (Stellite 6, Stellite 21), biocompatible cobalt-chromium alloys (CoCrNiMo, CoCrSi), emerging cobalt-chromium alloys (CoCrMo—Nb, CoCrW—Ni), Hastelloy® (C-276, X, B-3), and Invar® 36.

Turning now to musical instrument manufacturing in particular, in the past, various methods have been used and improvements made in the manufacturing process for musical instruments generally, as well as for particular types of musical instruments. For example, electroless plating has been applied in certain manufacturing processes for musical instruments. However, the application of electroless plating to musical instrument manufacturing has been employed only in limited ways, with its use currently restricted to intricate metal instrument parts and complex shapes.

Instances where the use of MAM has been described and used to construct a form of musical instrument are in the following examples: https://www.3deo.co/metal-3d-printing/the-unbreakable-guitar, https://www.oddguitars.com/heavymetal.html, https://www.researchgate.net/publication/344123217_The_Titanium_3D_Printed_Flute_new_prospects_of_additive_manufacturing_for_Musical_Wind_Instruments_Design. These projects used MAM to produce a musical instrument, or a portion of the musical instrument, to create a single unique item or for proof-of-concept.

Further, with respect to the manufacture of metal musical instruments, as noted, it is well known to utilize electroplating, particularly in the plating process for metal wind instruments. The process of electroplating musical instruments is the predominant form of metal and metal ally deposition on musical instruments which is reserved for solely metal musical instruments. While electroless plating has also been employed, currently its use is limited to a specific aesthetic for instruments, intricate instrument parts, complex shapes and components.

While improvements have been made over time in the manufacturing process of musical instruments, there is room for further improvement. Moreover, the current state of musical instrument production and techniques used can be time-consuming, expensive, damaging to the environment, and can lead to inconsistent results. Therefore, a need exists for a method of manufacturing and finishing wind instruments, sections, parts, and accessories that decreases manufacturing time and promote consistency, customization, and sustainable practices.

The present disclosure satisfies these needs and provides additional advantages.

### SUMMARY

In accordance with one embodiment of the present invention, a method for manufacturing at least one of a musical instrument, musical instrument section, musical instrument part, and musical instrument accessories is disclosed. The method comprises the steps of: utilizing computer-assisted drawing software to prepare a digital model of the at least one of the musical instrument, the musical instrument section, the musical instrument part, or the musical instrument accessory to be manufactured; slicing the digital model; selecting a material for the at least one of the musical instrument, the musical instrument section, the musical instrument part, or the musical instrument accessory to be manufactured; preparing the selected material; and building the digital model layer by layer using the material, until at least one of a three-dimensional musical instrument, musical instrument section, musical instrument part, or musical instrument accessory is formed.

In accordance with another embodiment of the present invention, a method for finishing a musical component, the musical component being one of a musical instrument, musical instrument section, musical instrument part, or musical instrument accessory, where in the composition comprises or contains a non-metal material, through which metals or metal alloys are deposited, is disclosed. The method comprises: selecting the musical component; preparing the component; preparing a bath; immersing the musical component in the bath, wherein metals or metal alloys are deposited on a surface of the musical component; rinsing the musical component; and post-process finishing the musical component.

In accordance with another embodiment of the present invention, a method for manufacturing and finishing a musical component is disclosed. The method comprises: utilizing computer-assisted drawing software for preparing a digital model of the musical component to be manufactured; slicing the digital model; selecting a material for the musical component; preparing the selected material; building the digital model layer by layer using the material until a three-dimensional component is formed utilizing a machine for a form of additive manufacturing; preparing the component to be metal plated; and depositing one of metals or metal alloys onto the surface of the three-dimensional musical component.

### BRIEF DESCRIPTION OF THE DRAWINGS

The present application is further detailed with respect to the following drawings.

These figures are not intended to limit the scope of the present application, but rather, illustrate certain attributes thereof. In the descriptions that follow, like parts are marked throughout the specification and drawings with the same numerals, respectively. The drawing figures are not necessarily drawn to scale and certain figures can be shown in exaggerated or generalized form in the interest of clarity and conciseness. The disclosure itself, however, as well as a preferred mode of use and further objectives and advantages thereof, can be best understood by reference to the following detailed description of illustrative embodiments when read in conjunction with the accompanying drawings, wherein:

FIG. 1 is a flowchart depicting the steps involved in an embodiment of the present disclosure;

FIG. 2 is a flowchart depicting the steps involved in an embodiment of the present disclosure; and FIG. 3 is a flowchart depicting the steps involved in an embodiment of the present disclosure.

### DESCRIPTION OF THE APPLICATION

The description set forth below in connection with the appended drawings is intended as a description of presently preferred embodiments of the disclosure and is not intended to represent the only forms in which the present disclosure can be constructed and/or utilized. The description sets forth the functions and the sequence of steps for constructing and operating the disclosure in connection with the illustrated embodiments. It is to be understood, however, that the same or equivalent functions and sequences may be accomplished by different embodiments that are also intended to be encompassed within the spirit and scope of this disclosure.

Embodiments of the present disclosure encompass a manufacturing process of using additive manufacturing, in general, to produce musical instruments, sections, parts, and accessories. More specifically, embodiments of the present disclosure encompass a manufacturing process of using metal additive manufacturing (hereinafter “MAM”) to produce musical instruments, sections, parts, and accessories. Utilizing MAM, complex or simple metal parts can be built layer-by-layer from a digital file. Embodiments of the present disclosure further encompass a manufacturing process of using non-metal additive manufacturing to produce musical instruments, sections, parts, and accessories. Utilizing non-metal additive manufacturing, complex or simple non-metal parts can be built layer-by-layer from a digital file. Embodiments of the present disclosure further encompass a finishing method using an autocatalytic process through which metals or metal alloys are deposited on musical instruments that are made from non-metal materials. Using this process can create a metal coating/plating on the surfaces of the non-metal materials. Embodiments of the present disclosure further encompass a manufacturing method of using additive manufacturing, in general, to produce musical instruments, sections, parts, and accessories and a finishing method for depositing one of metals or metal alloys onto the surface of the musical instruments, sections, parts, and accessories. Overall, using these methods of manufacturing and finishing, respectively, musical instruments, sections, parts, and accessories can improve the sound characteristics of such components and can drastically improve accuracy, replicability, designs, production flexibility, and material varieties, while reducing production time, skilled labor costs, material costs, and environmental impacts, as compared to traditional methods of manufacturing and producing musical instruments, sections, parts, and accessories.

With respect to musical instruments from one of the stated methods of manufacturing and finishing, for example, the model may comprise any musical instrument or other form of product designed primarily to produce sound in a musical context. The model may comprise any of a number of musical instruments from such commonly recognized categories as percussion, string, brass, woodwind, keyboard, and various contemporary electronic musical instruments, as well as various other instruments, as desired. Further, in the context of musical instruments, it should be noted that the term instrument, as commonly understood, may refer to the entirety of a musical instrument, including its sections and parts. While commonly recognized categories of musical instruments are referred to above, it should be clearly understood that substantial benefit could be derived from producing a model using one of the stated methods of manufacturing and finishing that comprises some other form of musical instrument that is not commonly known. With respect to sections of musical instruments, for example, the model may comprise any portion or area of an instrument, as distinguished from the instrument as a whole. Using the saxophone as an example, a saxophone section may comprise any whole or portion of such parts as the neck, body, bow, or bell, for example.

With respect to parts of musical instruments from one of the stated methods of manufacturing and finishing, the model may comprise any device/component employed for a musical instrument that is not part of the resonating portion of the instrument necessary for the functionality of the instrument. Again, using the saxophone as an example, a resonating portion of the instrument may include a resonating tube. Examples of parts of a saxophone distinct from the resonating tube may include (but not be limited to) such components as keys, screws, posts, resonators, and the like.

With respect to accessories for musical instruments from one of the stated methods of manufacturing and finishing, for example, the model may comprise any device employed for a musical instrument for a specific function that is not essential to the functionality of the musical instrument. Again, using the saxophone as an example, a non-essential device that can be used for a specific function for the instrument that is not integral to the functionality of the instrument may include (but not be limited to) such components as a mouthpiece cap, weighted device, key guard, and the like.

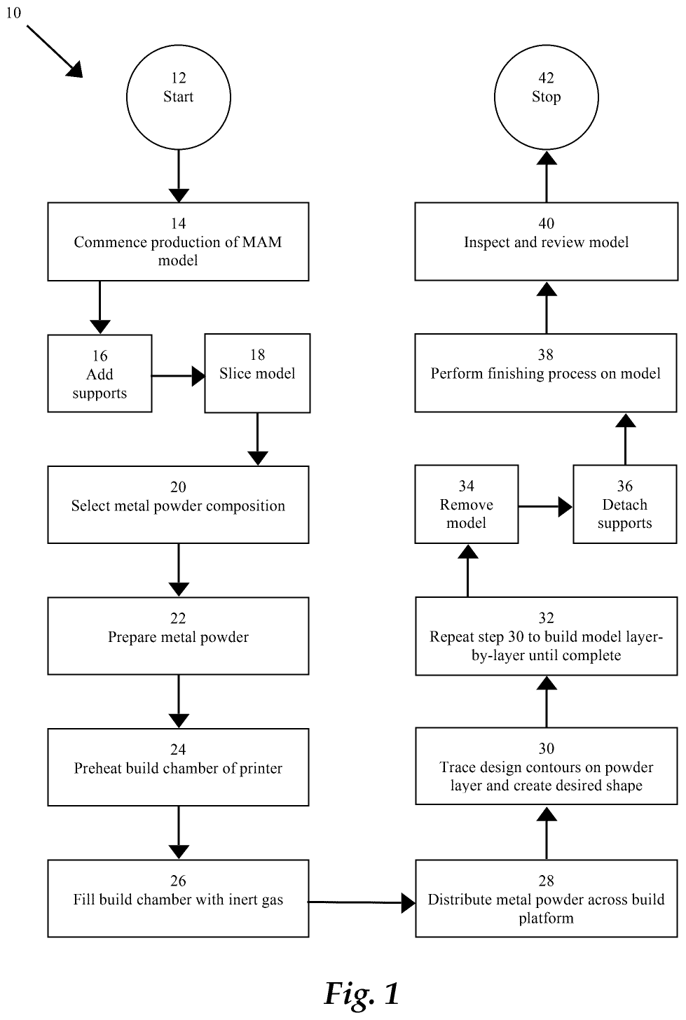

The manufacturing and finishing of musical instruments, sections thereof, and parts and accessories therefor utilizing the methods of the present disclosure are depicted in the flowcharts in FIGS. 1-3. Turning first to FIG. 1, a flowchart shows the steps of a method for manufacturing a musical instrument utilizing MAM (hereinafter the “method 10”), in accordance with an embodiment of the present disclosure. The method 10 is generally useful for manufacturing musical instruments, sections thereof, and parts and accessories therefor.

In one embodiment, the method 10 comprises the steps that follow. At step 14, production of a MAM model is commenced. In one embodiment, to begin a MAM model, a 3D design can be meticulously crafted by a user in a form of CAD software, creating a digital model. This digital model can dictate the particular component's every curve and contour, serving as the roadmap for the printing process. In one embodiment, any suitable form of CAD software may be employed, as desired by the user. In the context of the method 10, the MAM model may comprise various different forms of musical instruments, sections thereof, and parts and accessories therefor.

Referring again to FIG. 1, after the MAM model is created, in the next step, step 16, supports may be generated and added to the 3D model design for printing stability. Next, at step 18, slicing of the 3D model design may occur. In this regard, utilizing the CAD software, the model may be divided into multiple, relatively thin, planes or layers, with each such plane or layer serving as a pattern or instruction for the printer during the printing process as described further herein. Next, at step 20, a metal powder composition is selected. This selection may be made from a vast array of metal powders and compositions. For example, when crafting a MAM model of a saxophone body, it may be desired to utilize a metal powder comprised of brass or some other metal powder formulation, as may be desired. While in this embodiment the metal powder is described as being selected after the model has been sliced, it should be clearly understood that the metal powder may be selected at a different phase of the method 10 before the metal powder is prepared, and that the step of selecting the metal powder is not restricted to taking place after the model has been sliced.

After step 20, once the metal powder is chosen, next, at step 22, the metal powder is prepared. In one embodiment, preparation of the metal powder is conducted as may be needed, for example, ensuring the proper particle size and flow characteristic of the particular form of metal powder employed. In one embodiment, this preparation may require sieving and mixing to ensure such proper particle size and flow characteristics.

Next, when the model is ready to be printed, at step 24, the printer's build chamber is preheated. This preheating step may be accomplished according to the protocols and parameters required by the particular printer being utilized. In this step, the build chamber may be preheated to a specific temperature or suitable temperature range depending upon the form of metal selected at step 20 and the printing technology employed. Next, at step 26, an inert gas, such as argon, may fill the build chamber. Filling of the build chamber with the inert gas may be used to prevent oxidation and to maintain a safe environment. While argon is referenced as an example in this step, it should be clearly understood that another form of inert gas may be utilized, as may be necessary or desired, depending on the printing technology employed, the metals being used, and/or the form of model being created. Next, at step 28, a blade or roller distributes a thin layer of the selected metal powder across the build platform. Next, at step 30, a high-powered laser beam is used to trace the particular design contours on the powder layer, selectively melting or fusing the metal particles together. This precise melting creates the desired shape of the layer. In one embodiment, the shape of each layer follows the pattern of each layer established by slicing as noted in step 18. In addition to the model itself being printed, preferably, support structures are printed alongside the model. This serves to prevent drooping or warping during the build process.

The next step of the method 10 is to finish printing the model, creating the component, at step 32. In this step, the printer meticulously repeats step 30, building the particular object layer-by-layer, with the build platform lowering after each layer is completed. Once the printing is complete, next, at step 34, the component and any attached supports are removed from the printer. Then, at step 36 the supports are detached from the component and, at step 38, the component undergoes further finishing processes as may be needed or desired depending on the technique used. For example, in one embodiment, the printed component might undergo heat treatment in a furnace to relieve internal stresses and improve its mechanical properties. As another example, in one embodiment, a PBF component might require stress relieving, polishing, or sandblasting. As another example, in one embodiment, a PBF component may be polished and lacquered. As a further example, in one embodiment, BMD component may need debinding and sintering to achieve their final properties. Next, at step 40, the component preferably undergoes inspection and review for quality control purposes.

Utilizing the method 10 to produce musical instruments, sections thereof, and parts and accessories therefor offers distinct benefits and advantages. In this regard, while employing MAM, the method 10 allows for the production of relatively superior products using technology advancements to create modern manufacturing techniques for producing such musical instruments, sections thereof, and parts and accessories therefor. This is compared to such products'earlier counterparts manufactured using previously known conventional techniques. Manufacturing musical instruments, sections, parts, and accessories through MAM has the capability to greatly improve the accuracy and replicability of such products. As an example, with respect to saxophone manufacturing in particular, through conventional manufacturing techniques, the body of a saxophone is crafted in multiple halves. These parts need to be aligned and soldered by hand to create one uniform body. With MAM, the need for multiple parts to create one whole body is no longer required, in turn eliminating imperfections resulting from human error that can occur during aligning and soldering. Additionally, labor and the time traditionally required to complete an instrument can be substantially reduced by utilizing MAM, due to the entire construction process being completed by a printer without human intervention. The time to fully produce and assemble an instrument can be substantially reduced through the use of MAM compared to conventional methods, and could be a matter of days instead of weeks, months or longer, for example. Production preparation and flexibility is relatively easy utilizing MAM, due to the printer's ability to be set up to perform many different tasks. In addition to saxophone manufacturing, these advantages and benefits can be realized in the manufacturing of various other forms of musical instruments, sections, parts, and accessories utilizing the method 10, and it should be clearly understood that the method 10 is not limited to saxophone manufacturing; rather saxophone manufacturing is provided as an example only.

Further, some designs and configurations, impossible to manufacture and replicate with conventional processes, are now possible through the use of AM. For example, utilizing the method 10, an entire body of a saxophone, including the tone hole chimneys and bell, can be produced as a single unibody (i.e. one-piece) assembly with MAM. This is in contrast to conventional methods of manufacturing a saxophone as noted above. Further, using AM in this way has an added benefit, in that it can eliminate the need for seams formed along the body of an instrument, for example. This can substantially improve the sound, playability, intonation, and resonance of the instrument, as compared to instruments produced utilizing conventional manufacturing methods.

Further still, utilizing the method 10 to manufacture musical instruments, sections, parts, and accessories with MAM, a relatively greater variety of metals and alloys can be employed in musical instrument manufacturing, compared to conventional manufacturing methods. While conventional manufacturing of metal instruments has typically been restricted to brass and silver, with MAM, numerous different metals can be utilized, such as stainless steel (e.g. 316L, 17-4, 420, maraging steel), aluminum (e.g. AlSi10Mg, Al6061, Scalmalloy®), titanium (e.g. Ti6Al4V, grade 2, CP titanium), nickel alloys (e.g. Inconel® 625, IN718, Hastelloy® X), copper (e.g. C101, C102, C110), silver (e.g. sterling silver, silver-palladium alloys, silver-copper alloys; other special alloys, such as silver-gold alloys and silver-infiltrated metal powders), and brass (e.g. free-machining brass (C360), leaded brass (C260/C280), lead-free brass (C355), high-zinc brass (C510/C521), naval brass (C464), silicon brass, aluminum brass), for example. This wider selection and variation of materials can allow for new metal characteristics to be explored for musical instruments. In addition, the density of each metal can be varied, opening new possibilities in an instrument's tonal characteristics as well as weight reduction of the instrument compared to its traditional counterparts.

Yet another benefit from utilizing the method 10 to manufacture musical instruments, sections, parts, and accessories with MAM, is a reduction in environmental impact from manufacturing in general. In addition to the manufacture of other forms of products using MAM, this benefit can apply to the manufacturing of musical instruments, sections, parts, and accessories with MAM, as well. This process allows for intricate parts to be produced with relatively low to near-zero waste, in contrast to conventional, subtractive methods overflowing with metal chips. This transformative layer-by-layer approach of MAM conserves precious resources, reducing the environmental burden caused by extraction, processing, and transportation. MAM can become a powerful tool for achieving a more sustainable manufacturing future, minimizing waste and emissions while unleashing design possibilities previously constrained by traditional methods.

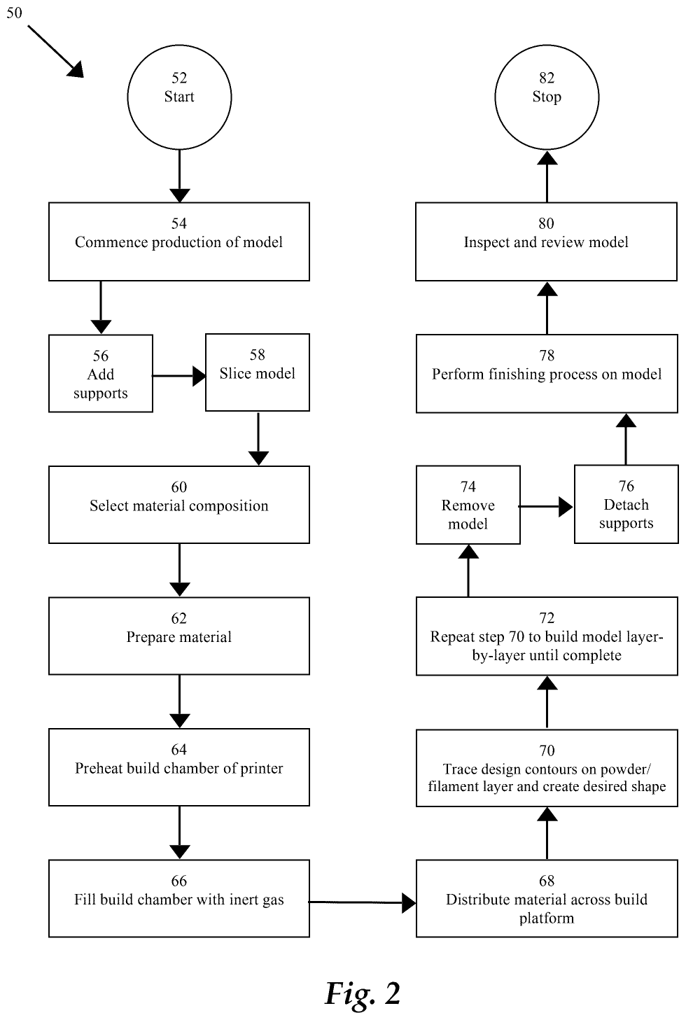

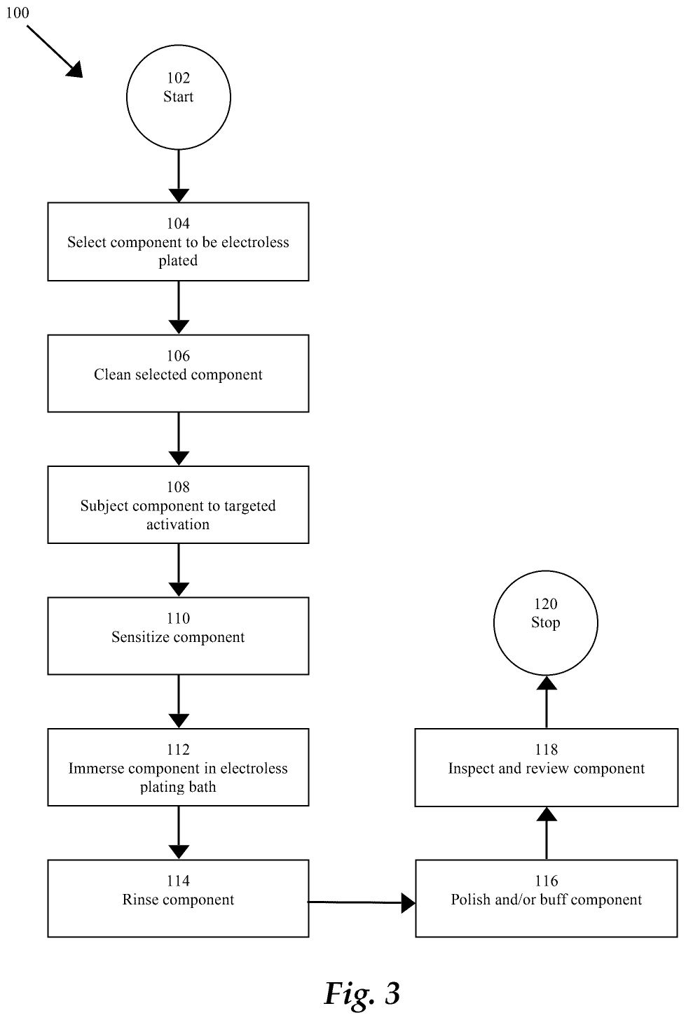

Turning now to FIG. 2, a flowchart shows the steps of a method for manufacturing a musical instrument utilizing non-metal additive manufacturing (hereinafter the “method 50”), in accordance with an embodiment of the present disclosure. The method 50 is somewhat similar to the method 10, but is designed for 3D printing of objects comprised of non-metal materials. The method 50 is generally useful for manufacturing musical instruments, sections thereof, and parts and accessories therefor.

In one embodiment, the method 50 comprises the steps that follow. At step 54, production of a non-metal additive manufacturing model is commenced. In one embodiment, to begin a non-metal additive manufacturing model, a 3D model design can be meticulously crafted in a form of CAD software, creating a digital blueprint. This digital blueprint can dictate the particular object's every curve and contour, serving as the roadmap for the printing process. In one embodiment, any suitable form of CAD software may be employed, as desired by the user. In the context of the method 50, the non-metal additive manufacturing model may comprise various different forms of musical instruments, sections thereof, and parts and accessories therefor. With respect to musical instruments, for example, the non-metal additive manufacturing model may comprise any musical instrument or other form of product designed primarily to produce sound in a musical context. The non-metal additive manufacturing model may comprise any of a number of musical instruments from such commonly recognized categories as percussion, string, brass, woodwind, keyboard, and various contemporary electronic musical instruments, as well as various other instruments, as desired. Further, in the context of musical instruments, it should be noted that the term instrument, as commonly understood, may refer to the entirety of a musical instrument, including its sections and parts. While commonly recognized categories of musical instruments are referred to above, it should be clearly understood that substantial benefit could be derived from producing a non-metal additive manufacturing model using the method 50 that comprises some other form of musical instrument that is not commonly known.

With respect to sections of musical instruments, for example, the non-metal additive manufacturing model may comprise any portion or area of an instrument, as distinguished from the instrument as a whole. Using the saxophone as an example, a saxophone section may comprise any whole or portion of such parts as the neck, body, bow, or bell, for example.

With respect to parts of musical instruments, the non-metal additive manufacturing model may comprise any device/component employed for a musical instrument that is not part of the resonating portion of the instrument necessary for the functionality of the instrument. Again, using the saxophone as an example, a resonating portion of the instrument may include a resonating tube. Examples of parts of a saxophone distinct from the resonating tube may include (but not be limited to) such components as keys, screws, posts, resonators, and the like.

With respect to accessories for musical instruments, for example, the non-metal additive manufacturing model may comprise any device employed for a musical instrument for a specific function that is not essential to the functionality of the musical instrument. Again, using the saxophone as an example, a non-essential device that can be used for a specific function for the instrument that is not integral to the functionality of the instrument may include (but not be limited to) such components as a mouthpiece cap, weighted device, key guard, and the like.

Referring again to FIG. 2, after the model is created, in the next step, step 56, supports are generated and added to the 3D model design for printing stability. Next, at step 58, slicing of the 3D model design may occur. In this regard, utilizing the CAD software, the model may be divided into multiple, relatively thin, planes or layers, with each such plane or layer serving as a pattern or instruction for the printer during the printing process as described further herein. Next, at step 60, a selection from a vast array of materials is considered, for whatever form or composition of materials will be suitable for the application of the particular model, as may be desired. While in this embodiment the material composition is described as being selected after the model has been sliced, it should be clearly understood that the material composition may be selected at a different phase of the method 50 before the material composition is prepared, and that the step of selecting the material composition is not restricted to taking place after the model has been sliced.

After step 60, once the material composition is chosen, at step 62, the material is prepared, as may be needed depending upon the particular formulation of material employed.

Next, when the model is ready to be printed, at step 64, the printer's build chamber is preheated. This preheating step may be accomplished according to the protocols and parameters required by the particular printer being utilized. In this step, the build chamber may be preheated to a specific temperature or suitable temperature range as may be needed depending upon the formulation of material selected at step 60 and the printing technology employed. Next, at step 66, depending upon the parameters that may be required by the printer employed and the particular materials utilized, an inert gas, such as argon, may fill the build chamber to prevent oxidation and to maintain a safe environment. While argon is referenced as an example in this step, it should be clearly understood that another form of inert gas may be utilized, as may be necessary or desired, depending on the printing technology employed, the metals being used, and/or the form of model being created. Next, at step 68, a thin layer of the selected material, which can be in powder or filament form, or the like, is distributed across the build platform. Next, at step 70, the particular design contours are traced on the powder or filament layer, selectively melting or fusing the material particles together utilizing parameters as may be needed depending upon the particular printer employed. This precise melting creates the desired shape of the layer. In one embodiment, the shape of each layer follows the pattern of each layer established by slicing as noted in step 58. In addition to the model itself being printed, preferably, support structures are printed alongside the model. This serves to prevent drooping or warping during the build process.

The next step of the method 50 is to finish printing the model at step 72. In this step, the printer meticulously repeats step 70, building the particular object layer-by-layer, with the build platform lowering after each layer is completed. Once the printing is complete, next, at step 74, the model and any attached supports are removed from the printer. Then, at step 76, the supports are detached from the model and, at step 78, the model undergoes further finishing processes as may be needed or desired depending on the technique used. For example, in one embodiment, the printed object might undergo heat treatment. As another example, in one embodiment, it may be desired to polish or sand the object to a smooth finish. Next, at step 80, the model preferably undergoes inspection and review for quality control purposes.

Utilizing the method 50 to produce musical instruments, sections thereof, and parts and accessories therefor offers distinct benefits and advantages. In this regard, while employing non-metal additive manufacturing, the method 50 allows for the production of relatively superior products using technology advancements to create modern manufacturing techniques for producing such musical instruments, sections thereof, and parts and accessories therefor. This is compared to such products'earlier counterparts manufactured using previously known conventional techniques. Manufacturing musical instruments, sections, parts, and accessories through non-metal additive manufacturing has the capability to greatly improve the accuracy and replicability of such products. As an example, with respect to saxophone manufacturing in particular, through conventional manufacturing techniques, the body of a saxophone is crafted in multiple halves. These parts need to be aligned and soldered by hand to create one uniform body. With non-metal additive manufacturing, the need for multiple parts to create one whole body is no longer required, in turn eliminating imperfections resulting from human error that can occur during aligning and soldering. Additionally, labor and the time traditionally required to complete an instrument can be substantially reduced by utilizing non-metal additive manufacturing, due to the entire construction process being completed by a printer without human intervention. The time to fully produce and assemble an instrument can be substantially reduced through the use of non-metal additive manufacturing compared to conventional methods, and could be a matter of days instead of weeks or months, for example. Production preparation and flexibility is relatively extremely easy utilizing non-metal additive manufacturing, due to the printer's ability to be set up to perform many different tasks. These advantages and benefits can be realized in the manufacturing of various forms of musical instruments, sections, parts, and accessories utilizing the method 50, and it should be clearly understood that the method 50 is not limited to saxophone manufacturing; rather saxophone manufacturing is provided as an example only.

Further, some designs and configurations, impossible to manufacture and replicate with conventional processes, are now possible through the use of non-metal additive manufacturing. For example, utilizing the method 50, an entire body of a saxophone, including the tone hole chimneys and bell, can be produced as a single unibody (i.e. one-piece) assembly with non-metal additive manufacturing. This is in contrast to conventional methods of manufacturing a saxophone as noted above. Further, using non-metal additive manufacturing in this way has an added benefit, in that it can eliminate the need for seams formed along the body of an instrument, for example. This can substantially improve the sound, playability, intonation, and resonance of the instrument, as compared to instruments produced utilizing conventional manufacturing methods.

Further still, utilizing the method 50 to manufacture musical instruments, sections, parts, and accessories with non-metal additive manufacturing, a relatively greater variety of materials can be employed in musical instrument manufacturing, compared to conventional manufacturing methods. While conventional manufacturing of traditional instruments has typically been restricted to particular materials, with non-metal additive manufacturing, numerous different materials can be utilized, such as polymers/plastics (e.g. ABS, polycarbonate and nylon; other thermoplastics include polypropylene, polyethylene, PTFE, PEEK, PETG, PMMA, POM, PVC and PVDF; common polymer thermosets include epoxy, phenolic, melamine, silicone and polyester); composites (e.g. fiberglass-reinforced plastics (FRP), carbon fiber-reinforced plastics (CFRP) and any other fiber-reinforced polymers); ceramics (e.g. alumina, zirconia, silicon nitride, silicon carbide, porcelain and the crystalline structure form of glass (in which atoms are arranged in a regular, repeating pattern); glass (e.g. any amorphous structure of glass (in which atoms are arranged randomly without a defined lattice; and other materials (wood, paper, and textiles), for example. This wider selection and variation of materials can allow for new material characteristics to be explored for musical instruments. In addition, the density of each material can be varied, opening new possibilities in an instrument's tonal characteristics as well as weight reduction of the instrument compared to its traditional counterparts.

Yet another benefit from utilizing the method 50 to manufacture musical instruments, sections, parts, and accessories with non-metal additive manufacturing, is a reduction in environmental impact from manufacturing in general. In addition to the manufacture of other forms of products using non-metal additive manufacturing, this benefit can apply to the manufacture of musical instruments, sections, parts, and accessories with non-metal additive manufacturing, as well. This process allows for intricate parts to be produced with relatively low to near-zero waste, in contrast to conventional manufacturing techniques. This transformative layer-by-layer approach of non-metal additive manufacturing conserves precious resources, reducing the environmental burden caused by extraction, processing, and transportation. Non-metal additive manufacturing can become a powerful tool for achieving a more sustainable manufacturing future, minimizing waste and emissions while unleashing design possibilities previously constrained by traditional methods.

Turning now to FIG. 3, generally, a flowchart shows the steps of a method for finishing a musical instrument utilizing electroless plating (hereinafter the “method 100”), in accordance with an embodiment of the present disclosure. The method 100 is generally useful for finishing manufactured musical instruments, sections thereof, and parts and accessories therefor that are comprised of non-metal materials. Such musical instruments can be manufactured through the process of non-metal additive manufacturing, as in the method 50, and then finished utilizing the method 100. Alternatively, such musical instruments can be manufactured according to conventional methods and then finished utilizing the method 100. While in the discussion below the method is described as being applied to musical instruments comprised of non-metal materials, it should be clearly understood that electroless plating is a process that can also be applied to metallic materials, as commonly known and understood by those of skill in the relevant art. It should also be noted that musical instruments finished with method 100 may comprise any of a number of different types of musical instruments, sections thereof, and parts and accessories therefor, as may be desired.

In one embodiment, the method 100 comprises the steps that follow. At step 104, a desired component, comprising a musical instrument, section thereof, and/or part or accessory therefor (hereinafter “component”) is selected for the electroless plating process. In one embodiment, the component selected may comprise a component manufactured utilizing the method 50. In another embodiment, the component selected may comprise a component manufactured utilizing conventionally known methods. Next, at step 106, the component is cleaned. During this step, preferably, the component is meticulously cleaned in order to expel unwanted grime and oils from the component and to promote adhesion of the plating substance. To clean the component in preparation for electroless plating, preferably, relatively strong detergents or alkaline solutions which effectively remove oils, greases, and organic contaminants are used. To enhance the cleaning process, an ultrasonic bath can be used. For improved adhesion, mild or moderate acid etchants, such as sulfuric or chromic acid, can be used to etch the plastic surface, creating microscopic roughness. Additionally, abrasive blasting through processes such as sand-blasting, glass bead blasting, and/or plasma cleaning can be used for specific plastics, as desired, to further enhance adhesion.

It should be noted that during cleaning in step 106, different cleaning processes may be utilized to suit the particular composition of the component to be cleaned. For example, with respect to components comprised of polymers/plastics, cleaning of a polymer/plastic object involves solvents, detergents and plasma cleaning. The specific solvents used can include acetone, isopropanol, and, sometimes, alkaline cleaners. The detergents used can include mild soaps or commercially available cleaners. Finally, plasma cleaning can be used for 5-10 minutes on a low pressure with an inert gas. As another example, for components comprised of composites, composites have a pre-treatment cleaning phase similar to that of polymers, with additional considerations for the individual matrix and fiber/filler materials used with composites. Further, some composites might require specific cleaning or activating solutions. As a further example, for components comprised of ceramics, cleaning is crucial. Special attention might be needed for removing organic residues from the ceramic components utilizing strong solvents. Abrasive cleaning (such as grit blasting), plasma etching, or laser ablation could be necessary for optimal activation. As a further example, for components comprised of wood, pre-treatment of wood consists of ensuring the wood is dry and free of any contaminants. Sealing might be necessary for some woods to prevent solution absorption. The wood type utilized and the potential reactivity that may occur with the chosen plating solution must be considered. As another example, for components comprised of paper, the pre-treatment phase of paper is similar to that of wood, with additional considerations regarding its fragility. Gentle cleaning methods need to be used and proper drying ensured before activation. As a further example, for components comprised of rubber, the pre-treatment phase begins with choosing appropriate cleaning methods based on the type of rubber utilized. Some rubber types might require specific activation techniques such as chlorination or silane coupling agents. As a further example, for components comprised of textiles, the pre-treatment phase consists of removing impurities using enzymes at a temperature or temperatures suitable for the particular enzymes, and an optional mercerization cleaning solution. Impurities such as sizing and oils are cleaned. Enzymes or mild detergents with specific considerations for fabric type and colorfastness are then used on the textile at a temperature between 40-60° C. for 15-30 minutes. An additional mercerization cleaning solution can be used to improve dye and plating uptake for cellulose-based fabrics. This is a sodium hydroxide solution (20-30%) used for 15-30 minutes. This solution requires careful rinsing and neutralization when completed.

Referring again to FIG. 3, after the subject component is cleaned, in the next step, step 108, the subject component undergoes a targeted activation treatment in order to roughen its surface. With the surface of the subject component roughened, this promotes adherence of the metal coating that is to be applied during the electroless plating process, as noted further herein. Preferably, the activation step can include a chemical etch, plasma treatment, or the like. It should be noted that in preparation for electroless plating, certain plastics, such as acrylonitrile butadiene styrene (hereinafter “ABS”), require a sensitization step using stannous chloride solution that activates the surface for subsequent activation. Palladium or tin chloride solutions act as activators, depositing catalytic ions onto the roughened surface. These ions attract and bind the metal ions from the plating solution.

It should be noted that during activation in step 108, different activation processes may be utilized to suit the particular composition of the subject component. For example, with respect to components comprised of polymers/plastics, activation of a polymer/plastic object undergoes an enhanced adherence process of roughening the surface. Chemical etching is a common technique used on ABS, for example. It is a process that uses chromic acid (5-10%) and acidic stannous chloride for 10-30 minutes. Another technique that is used is corona treatment that occurs at 10-30 kV for 10-60 seconds. The final technique used for polymer/plastic objects is flame treatment. This technique involves using a specific flame type suitable for the particular polymer/plastic composition at a controlled distance. As another example, for components comprised of textiles, the activation of the textile object undergoes a sensitization process after it is cleaned, as discussed further herein.

After step 108, the subject component is sensitized at step 110. During the sensitization process at step 110, a catalyst layer is applied. This catalyst layer acts as a bridge between the non-metal material of the subject component and the metal ions that are waiting in an electroless plating bath (into which the subject component will be placed, as discussed further below).

It should be noted that during sensitization step 110, different sensitization processes may be utilized to suit the particular composition of the subject component. For example, with respect to components comprised of polymers/plastics, the final pre-treatment step is sensitization.

Sensitization applies a catalyst layer that binds both to the polymer and the plating solution. A palladium chloride solution (0.1-1 g/L) and a stannous chloride activator are used for 5 -15 minutes at a temperature of 20-40° C. As another example, with respect to textiles, similar to the sensitization process used for polymers, the sensitization process for textiles uses a palladium chloride solution and activator. This solution is typically used at a temperature from 20-40° C. for 5 -15 minutes.

Next, at step 112, the subject component is immersed in an electroless plating bath, where metal ions build a metallic layer on the subject component atom by atom. During this step, the plating process commences. The bath solution preferably contains metal ions dissolved in a relatively complex mix of chemicals that can include complexing agents, stabilizers, and buffers. The specific composition used for the electroless plating bath can vary depending on the desired metal used to plate the subject component, as well as the properties of the desired metal. Formaldehyde, borohydride, or other reducing agents donate electrons to the metal ions, reducing them to neutral metal atoms. This transformation activates the metal atoms for bonding with the activated plastic surface. Palladium or tin ions, present in trace amounts, act as catalysts. They accelerate the reduction process, ensuring uniform and continuous metal deposition.

Controlled temperatures within a specific range (typically 40-60° C.) can optimize the plating reaction and ensure proper coating quality. Maintaining a stable pH in the plating bath is crucial for controlled deposition and adhesion. Gentle agitation of the bath can ensure uniform exposure of the plastic surface (or other formulation of the surface) of the subject component to the plating solution, leading to a consistent metal coating.

It should be noted that during the plating process at step 112, different processes may be utilized to suit the particular composition of the subject component. For example, with respect to components comprised of polymers/plastics, the polymer/plastic object is plated by immersing it for 15-60 minutes in the electroless plating bath containing metal ions, reducing agents, and complexing agents. The metal ions are deposited onto the activated surface via the catalyst layer. The bath components consist of a metal salt, reducing agent, complexing agents, stabilizers, and pH adjusters. The electroless plating bath's temperature typically ranges from 60-90° C. with a pH level ranging from pH 4-10. As another example, for components comprised of composites, when plating a composite, the potential reactivity of the composite components with the plating solution needs to be considered. This can require selecting compatible solutions and adjusting parameters (such as temperature, pH, and time) as may be needed depending on the particular composition of the composite materials. As a further example, for components comprised of ceramics, there are specialized electroless plating solutions designed for ceramics. Such solutions often involve strong oxidizing agents to prepare the surface of the ceramic material. As a further example, for components comprised of wood, as with ceramics, there are specialized electroless plating solutions for wood, which often contain formaldehyde-free formulations. As another example, for components comprised of paper, the electroless plating process of paper also has specialized solutions suitable for paper's composition. Such solutions may be configured to help avoid shrinkage or distortion that may occur during the plating process of paper. As another example, for components comprised of rubber, specialized electroless plating solutions exist for the plating phase. Often, this process utilizes specific catalysts and complexing agents for adhesion. As yet another example, for components comprised of textiles, the plating of a textile object begins when a catalytic layer of metal deposition is added, typically using a formaldehyde-free formulation preferred for environmental and health reasons. This typically occurs at a temperature between 20-40° C. for 5-10 minutes. The plating bath solution is similar to that used for polymers, but often with added complexing agents for textile compatibility. The temperature of the bath is typically between 30-60° C. The bath solution typically has a pH level of 4-10 and is used for 15-60 minutes.

After plating at step 112, next, at step 114, the subject component is rinsed. During this step, multiple rinses with water or deionized water may be performed to remove any residual chemicals and prevent contamination. Some plating processes might require an acidic or alkaline bath to neutralize any remaining activation or plating chemicals., depending on the particular process utilized. After the multiple rinses are complete, a final rinse can be performed.

It should be noted that that during the rinsing process at step 114, different processes may be utilized to suit the particular composition of the subject component. For example, with respect to components comprised of polymers/plastics, the final phase for electroless plating of polymers/plastics is the post-treatment phase. This phase consists of rinsing, drying, and finishing the component. First, the polymer/plastic component is rinsed with deionized water and ultrasonic agitation for a thorough cleaning. Next, an oven may be used to dry the component. Finally, optional polishing, painting, or other surface treatments may be done to the component to bring it to completion. As another example, for components comprised of composites, the post-treatment phase for composites is similar to that of polymers. Like the plating process, the compatibility of finishing processes with all composite materials needs to be ensured. As a further example, for components comprised of ceramics, the post-treatment phase for ceramics is similar to that used for polymers and composites, with additional focus on maintaining the integrity of the ceramic material during drying and finishing. As another example, for components comprised of wood, the post-treatment phase of electroless plating of wood includes carefully drying the wood to prevent warping or cracking, followed by sanding or polishing. As another example, for components comprised of paper, the post-treatment phase of drying and finishing plated paper requires delicacy, due to the paper's fragile nature. Other methods of strengthening the object may need to be considered. As another example, for components comprised of rubber, potential swelling or shrinkage during drying can occur during the post-treatment phase of electroless plating of rubber. Accordingly, choosing a compatible finishing method to avoid damaging the rubber is important. As yet another example, for components comprised of textiles, rinsing the textile in deionized water with ultrasonic agitation is recommended for thorough cleaning during the post-treatment phase. Next, neutralization to adjust pH back to a neutral range can take place if necessary. To dry the textile, air drying or gentle tumble drying at low temperatures may be used. Finally, to finish the textile, optional additional treatments such as softening, wrinkle-proofing, or waterproofing can be used.

After rinsing at step 114, next, at step 116, the subject component can be polished or buffed, as desired, depending on the particular application employed during the electroless plating process. Polishing and/or buffing can achieve a specific finish, enhance shine, and/or remove minor imperfections, as may be desired. Certain plating processes, such as electroless nickel, may benefit from heat treatment to improve wear resistance and adhesion. After completion of this step, the subject component, once non-metal, now is conductive, being plated in metal. Next, at step 118, the subject component preferably undergoes inspection and review for quality control purposes.

Utilizing the method 100 to plate (i.e. metal coat) musical instruments, sections thereof, and parts and accessories therefor offers distinct benefits and advantages. In this regard, while employing electroless plating, the method 100 allows for musical instruments, sections thereof, and parts and accessories therefor comprised of non-metallic materials to be plated in metal. Plating musical instruments, sections thereof, and parts and accessories therefor can improve the look and feel of such components, thereby creating more aesthetically pleasing products. Further, plating musical instruments, sections thereof, and parts and accessories therefor comprised of non-metal materials improves the functionality of such components. In this regard, plating in metal enhances the strength, durability and corrosion resistance of such components specifically, as well as objects in general. Additionally, plating creates a smoother surface, compared to non-plated materials, which can improve the performance of a part/component. Further still, plating with biocompatible metals can create relatively safer final products and can allow for a wider selection of building materials to be utilized for musical instruments, sections thereof, and parts and accessories therefor, compared to their conventional counterparts.

Another exemplary benefit resulting from plating a musical instrument comprised of non-metal materials is that the instrument's acoustic characteristics can be altered advantageously. In this regard, a musical instrument that is plated will generally be capable of louder sound production and have more projection when compared to an instrument comprised of a non-metal material. This is a result of the sound and vibration, produced by the instrument, being reflected off the harder surface of the metal plating, instead of being absorbed by a comparatively softer non-metal material. Further, a wider selection of tonal qualities, characteristics, and possibilities is available with plating instruments comprised of non-metal materials.

As a further benefit, non-metal material instruments are generally less expensive to manufacture compared to fully metal instruments. Thus, the capability of plating a non-metal material instrument offers distinct economical benefits of manufacturing instruments from less expensive non-metal materials, while offering distinct performance benefits of superior tonal characteristics and aesthetics traditionally held by metal instruments.

The foregoing description is provided to enable any person skilled in the relevant art to practice the various embodiments described herein. Various modifications to these embodiments will be readily apparent to those skilled in the relevant art, and generic principles defined herein can be applied to other embodiments. Thus, the claims are not intended to be limited to the embodiments shown and descried herein, but are to be accorded the full scope consistent with the language of the claims, wherein reference to an element in the singular is not intended to mean “one and only one” unless specifically stated, but rather “one or more. ” All structural and functional equivalents to the elements of the various embodiments described throughout this disclosure that are known or later come to be known to those of ordinary skill in the relevant art are expressly incorporated herein by reference and intended to be encompassed by the claims. Thus, the foregoing description is illustrative of particular embodiments of the application, but is not meant to be a limitation upon the practice thereof. The following claims, including all equivalents thereof, are intended to define the scope of the application.

What is claimed is:

1. A method for manufacturing at least one of a musical instrument, musical instrument section, musical instrument part, and musical instrument accessories, comprising the steps of:
utilizing computer-assisted drawing software to prepare a digital model of the at least one of the musical instrument, the musical instrument section, the musical instrument part, or the musical instrument accessory to be manufactured;
slicing the digital model;
selecting a material for the at least one of the musical instrument, the musical instrument section, the musical instrument part, or the musical instrument accessory to be manufactured;
preparing the selected material; and
building the digital model layer by layer using the material, until at least one of a three-dimensional musical instrument, musical instrument section, musical instrument part, or musical instrument accessory is formed.

2. The method of claim 1, comprising utilizing a machine for a form of additive manufacturing.

3. The method of claim 1, comprising post processing at least one of the three-dimensional musical instrument, musical instrument section, musical instrument part, or musical instrument accessory.

4. The method of claim 3, wherein post processing comprises heat treating the at least one of the three-dimensional musical instrument, musical instrument section, musical instrument part, or musical instrument accessory.

5. The method of claim 3, wherein post processing comprises one of lacquering or coating at least one the three-dimensional musical instrument, musical instrument section, musical instrument part, or musical instrument accessory.

6. The method of claim 2, wherein the form of additive manufacturing uses a thermal source.

7. The method of claim 2, wherein the form of additive manufacturing uses a binding agent.

8. The method of claim 1, wherein the selected material is a metal in powder form.

9. The method of claim 1, wherein preparing the selected material comprises one of sieving and mixing.

10. The method of claim 2, wherein the form of additive manufacturing is metal additive manufacturing.

11. The method of claim 8 wherein the selected material is comprised of a metal formulation.

12. The method of claim 2, wherein the form of additive manufacturing is non-metal additive manufacturing.

13. The method of claim 8, wherein the selected material is comprised of a non-metal formulation.

14. The method of claim 1, wherein the selected material is in one of a filament form and a liquid form.

15. A method for finishing a musical component, the musical component being one of a musical instrument, musical instrument section, musical instrument part, or musical instrument accessory, wherein the composition comprises or contains a non-metal material, through which metals or metal alloys are deposited, comprising:
selecting the musical component;
preparing the component;
preparing a bath;
immersing the musical component in the bath, wherein metals or metal alloys are deposited on a surface of the musical component;
rinsing the musical component; and
post-process finishing the musical component.

16. The method of claim 15, wherein post-processing the musical component comprises one of polishing and buffing the musical component.

17. The method of claim 15, wherein the musical component is comprised of a non-metal material having the metals or metal alloys deposited on the surface of the musical component.

18. The method of claim 17, wherein the non-metal material is formed of one of a polymer, plastic, thermoplastic, composite, ceramic, glass, wood, paper, rubber, or textile.

19. A method for manufacturing and finishing a musical component, comprising:
utilizing computer-assisted drawing software for preparing a digital model of the musical component to be manufactured;
slicing the digital model;
selecting a material for the musical component;
preparing the selected material;
building the digital model layer by layer using the material until a three-dimensional component is formed utilizing a machine for a form of additive manufacturing;
preparing the component to be metal plated; and
depositing one of metals or metal alloys onto the surface of the three-dimensional musical component.

20. The method of claim 19, comprising finishing the three-dimensional component by one of polishing and buffing.

21. The method of claim 19, wherein the musical component is one of a musical instrument, a section of a musical instrument, a part of a musical instrument, or an accessory for a musical instrument.

22. The method of claim 19, wherein the material composition is formed of at least one of a metal, metal alloy, polymer, plastic, thermoplastic, composite, ceramic, glass, wood, paper, or textile.

23. The method of claim 19, wherein the deposing one of metals or metal alloys comprises electroplating the three-dimensional component.

24. The method of claim 19, wherein deposing one of metals or metal alloys comprises electroless plating the three-dimensional component.
